(19) United States
(12) Patent Application Publication
(10) Pub. No.: US 2024/0319273 A1
(43) Pub. Date: Sep. 26, 2024

(54) CIRCUIT TESTING

(71) Applicant: Nordic Semiconductor ASA, Trondheim (NO)

(72) Inventors: Linda KRISTOFFERSEN, Trondheim (NO); Ashraf MOHAMMED, Trondheim (NO)

(73) Assignee: Nordic Semiconductor ASA, Trondheim (NO)

(21) Appl. No.: 18/612,710

(22) Filed: Mar. 21, 2024

(30) Foreign Application Priority Data
Mar. 24, 2023 (GB) 2304357.3

(51) Int. Cl. G01R 31/3185

(52) U.S. Cl. CPC G01R 31/318541

(57) ABSTRACT

A circuit portion is disclosed comprising an operational input and a scan input; a logic portion comprising at least one input and at least one output; and a first scan latch comprising at least one input and at least one output. The circuit portion is arranged to operate in an operational mode in which the operational input is connected to an input of the logic portion and the logic portion operates as an asynchronous latch to generate an operational output signal at an output of the logic portion; and a scan mode in which the logic portion operates as part of a second scan latch, and the first scan latch and the second scan latch form a synchronous flip-flop comprising an input connected to the scan input and arranged to generate a scan output signal.

### CROSS REFERENCE TO RELATED APPLICATION

This application claims priority from Great Britain Application No. 2304357.3, filed Mar. 24, 2023, which application is incorporated herein by reference in its entirety.

### BACKGROUND OF THE INVENTION

The present invention relates to circuit portions featuring asynchronous logic and to the testing of these circuit portions.

To aid robustness and reliability, many logic circuits today are “designed for testing” (DFT). DFT circuits include components that facilitate testing processes.

One common method for testing circuits is scan testing, where test patterns of signals are input into various nodes of a device under test (DUT), and the response of the circuit to each pattern is observed. Circuits often include dedicated scan test components which can function as scan signal input and observation points during scan testing. Test equipment may apply test vectors generated by automatic test pattern generation (ATPG) software and analyse the results.

Typically, flip-flops are used as the scan input and observation points. Modified “scannable” flip-flops (commonly referred to as scan cells) include additional scan inputs and outputs. A DUT may be placed into a scan mode by asserting a test mode signal which switches the input of the scan cells of the device over to the scan input. The scan inputs and scan outputs of several scan cells in a DUT can be chained together to form a shift register (a scan chain). A scan test pattern can then conveniently be loaded into all of the scan cells, a capture cycle performed, and then resulting states of the scan cells can be conveniently read out.

Scan cells are relatively straightforward to incorporate in devices using synchronous logic by simply adding a multiplexer to the input of flip-flops in the synchronous logic that allows the input of the flip-flop to be switched between an operational input and a scan input.

However, increasing numbers of devices are now utilising asynchronous logic (i.e. logic that does not operate according to a repeating clock signal) to which scan testing capabilities cannot as easily be added. Asynchronous logic often features feedback loops which can make it difficult to produce desired starting conditions for testing. It has been proposed to enable scan testing of circuits that use asynchronous logic by adding scannable flip-flops which bypass portions of asynchronous logic (e.g. latches) to break feedback loops and add scan testing points. However, this approach causes portions of logic to be omitted from testing, and can substantially increase the component count and area of the circuit.

An improved approach may be desired.

### SUMMARY OF THE INVENTION

According to a first aspect of the present invention there is provided a circuit portion comprising:
an operational input and a scan input;
a logic portion comprising at least one input and at least one output; and
a first scan latch comprising at least one input and at least one output;
wherein the circuit portion is arranged to operate in:
an operational mode in which the operational input is connected to an input of the logic portion and the logic portion operates as an asynchronous latch to generate an operational output signal at an output of the logic portion; and
a scan mode in which the logic portion operates as part of a second scan latch, and the first scan latch and the second scan latch form a synchronous flip-flop comprising an input connected to the scan input and arranged to generate a scan output signal.

It will be appreciated by those skilled in the art that the circuit portion may facilitate scan testing of asynchronous logic that is more accurate and utilises fewer components than conventional approaches. It is advantageous to facilitate scan testing of asynchronous logic because of the potential speed, area and power consumption benefits associated with asynchronous logic.

Because the logic portion used in the operational mode is used as a part of a scan latch in the scan mode, scan testing carried out using the scan mode may be more representative of actual circuit operation, e.g. compared to conventional approaches in which asynchronous logic is bypassed in a scan mode. This may allow for more accurate and comprehensive testing of the circuit portion. For instance, the logic portion may operate as a memory element of the second scan latch in the scan mode. In some embodiments the logic portion may comprise a latch which is simply re-purposed as the second scan latch in the scan mode.

Re-using the logic portion in the second scan latch in the scan mode may reduce the amount of additional circuitry needed to provide the scan mode functionality, allowing the component count and area of the circuit portion to be reduced. A separate flip-flop may not need to be provided to add scan test functionality to the circuit portion. The circuit portion may be one of a large number in a device, so minimising the area and component count of each circuit portion can lead to significant size and cost benefits.

It will be recognised that the synchronous flip-flop is a master-slave type flip-flop comprising master and slave latches. In a set of embodiments, the first scan latch is the master latch and the second scan latch is the slave latch. In such embodiments, the input of the first scan latch may be connected to the scan input. In the scan mode, the input of the logic portion may be connected to the output of the first scan latch, and the scan output signal may be generated at the output of the logic portion.

Alternatively, in a set of embodiments the second scan latch is the master latch and the first scan latch is the slave latch. In such embodiments, the input of the first scan latch may be connected to the output of the logic portion. In the scan mode, the scan input is connected to the input of the logic portion and the scan output signal may be generated at the output of the first scan latch.

In a set of embodiments, the first scan latch and/or the second scan latch (i.e. the master latch and/or the slave latch) is a D-latch. The scan input may be a data input for the master D-latch. The output of the logic portion may be a positive output of the master D-latch. The input of the slave latch may be a data input of the slave D-latch. The scan output signal may be provided at a positive output of the slave D-latch.

In contrast to the logic portion in the operational mode, the flip-flop formed in the scan mode is synchronous, i.e. the synchronous flip-flop is clocked by a scan clock signal. The scan input cascades through the master and slave latches to be output as the scan output signal after a delay which depends on the clock signal. The master latch may be clocked by a scan clock signal and the slave latch may be clocked by an inverted version of the scan clock signal (or vice-versa). In such embodiments a signal at the scan input cascades through the master and slave latches to be output as the scan output signal after a delay corresponding to one tick of the scan clock signal (i.e. the time taken for one rising edge and one falling edge of the scan clock signal). The circuit portion may comprise a scan clock input arranged to receive a scan clock signal that clocks the synchronous flip-flop.

The circuit portion may be arranged to connect one or more logic elements in input and/or output paths of the logic portion to operate the logic portion as part of the second scan latch in the scan mode (e.g. a memory element thereof). For instance, the circuit portion may be arranged to gate an input of the logic portion with an enable signal (e.g. using an AND gate) when in the scan mode. The enable signal may be derived from the clock signal of the synchronous flip-flop (e.g. a scan clock signal). In other words, the circuit portion may be arranged to gate an input of the logic portion with an enable signal derived from the scan clock signal when in the scan mode.

Once the scan mode has been used to load a test state into the logic portion, the circuit portion may simply be put back into the operational mode to react asynchronously to the test state. However, in a set of embodiments the circuit portion is arranged to operate in a capture mode in which the operational input is connected to the input of the logic portion and the logic portion operates as part of the second scan latch of the synchronous flip-flop. The effect of a test state loaded in the scan mode can then be tested synchronously according to the clock of the flip-flop, with the result being captured by the slave latch (i.e. whichever of the first or second scan latches is arranged to operate as the slave latch). The circuit portion may be arranged to perform a scan capture cycle using the capture mode.

The mode in which the circuit portion operates may be controlled by one or more control signals. For instance, in some embodiments the circuit portion may comprise a scan enable input arranged to receive a scan enable signal. The scan enable signal may be used to control whether the operational input is connected to the input of the logic portion. The scan enable signal may control an input multiplexer. In embodiments where the first scan latch is the master latch of the synchronous flip-flop and the second scan latch is the slave latch of the synchronous flip-flop, the scan enable signal may control whether the operational input or the output of the first scan latch is connected to the input of the logic portion. In embodiments where the first scan latch is the slave latch of the synchronous flip-flop and the second scan latch is the master latch of the synchronous flip-flop, the scan enable signal may control whether the operational input or the scan input is connected to the input of the logic portion.

In some embodiments, additionally or alternatively, the circuit portion comprises a test mode input arranged to receive a test mode signal. The test mode signal may control enabling of the first scan latch. The test mode signal may control whether the input to the logic portion is gated by a clock signal, i.e. to control whether the logic portion operates synchronously or asynchronously.

In a set of embodiments the scan enable signal and the test mode signal together control whether the circuit portion operates in the operational mode, the scan mode or, in relevant embodiments, the capture mode. For instance, the circuit portion may be arranged to operate in the operational mode when the scan enable signal and the test mode signal are logic low and to operate in the scan mode when the scan enable signal and the test mode signal are logic high. The circuit portion may be arranged to operate in the capture mode when the scan enable signal is logic low and the test mode signal is logic high.

The circuit portion may comprise configuration circuitry for facilitating the different modes of the circuit portion. The configuration circuitry may be controlled by control signals such as the scan enable signal and/or the test mode signal. The configuration circuitry may comprise one or more AND gates, one or more OR gates, one or more inverters, one or more XOR gates and/or one or more multiplexers arranged to provide appropriate signals to the logic portion and the first scan latch in the operational scan and capture modes.

In a set of embodiments, the logic portion comprises a mutual-exclusion (MUTEX) element. The MUTEX element may comprise first and second request inputs and at least one grant output. The MUTEX element may be arranged to output a signal on the at least one grant output according to an order in which asserted signals are applied to the first and second request inputs. For instance, the MUTEX element may comprise a first grant output arranged to assert a grant signal if a request signal is asserted on the first request input before the second request input. The MUTEX element may comprise a second grant output arranged to assert a grant signal if a request signal is asserted on the second request input before the first request input. The MUTEX element may have both first and second grant outputs. The MUTEX element (also sometimes referred to as an arbiter) may be understood as only allowing one input through at a time.

In a set of embodiments, the logic portion comprises a set-reset latch (an SR or RS latch). The SR latch may comprise a set input and a reset input and at least one output. The SR latch may be arranged to latch the output to logic high if a logic high signal is asserted on the set input until a logic high signal is asserted on the reset input. The SR latch may comprise a negative output comprising the inverse of the output. In some embodiments the SR latch comprises a pair of logic gates connected with a cross-feedback loop (i.e. where the output of each gate acts as an input to the other). For instance, the SR latch may comprise a pair of NOR gates in a cross-feedback configuration and with each NOR gate having an input connected to a respective one of the set and reset inputs. Alternatively, the SR latch may comprise a pair of NAND gates in a cross-feedback configuration and with each NAND gate having an input connected to a respective inverted one of the set and reset inputs.

In a set of embodiments, the logic portion comprises a D-latch. The D-latch may comprise a data input, an enable input and at least one data output. The D-latch may be arranged to latch the data output to the state of the data input when a logic high signal is asserted on the enable input. The D-latch may comprise a negative data output comprising the inverse of the data output.

The circuit portion may be arranged to generate the operational and scan output signals at separate physical outputs (e.g. arranged to generate the operational output at an output of the logic portion and the scan output at an output of the first scan latch). In other words, the circuit portion may comprise an operational output for outputting the operational output signal and a separate scan output for outputting the scan output signal. These outputs may be external outputs of the circuit portion, e.g. to allow the operational and scan output signals to be sent separately to other components.

However, in a set of embodiments, the circuit portion may be arranged to generate the operational and scan output signals at the same physical output. In other words, the circuit portion may comprise a single output for outputting the operational output signal and the scan output signal. For instance, in embodiments where the first scan latch is the master latch and the second scan latch is the slave latch of the synchronous flip-flop, the operational and scan output signals may both be generated at an output of the logic portion. In embodiments where the first scan latch is the slave latch and the second scan latch is the master latch of the synchronous flip-flop, the output of the first scan latch and the output of the logic portion may be connected to a single circuit portion output via a multiplexer arranged to select the output of the logic portion in the operational mode and the output of the first scan latch in the scan mode.

The circuit portion preferably operates using digital logic signals, i.e. having a logic low or a logic high state. These logical states may be implemented by raising or lowering a voltage on an electrical conductor. For instance, a logical high state may comprise the assertion of a first voltage on a connection between two components, and a logical low state may comprise the assertion of a second voltage on a connection between two components.

As explained above, the scan mode facilitates the testing of the individual circuit portion. However, devices often include large numbers of circuit portions that work together to provide the device's functionality. Comprehensive testing of such devices may benefit from being able to set and observe states of many or all of the circuit portions. Whilst it may in principle be possible to input scan data directly to each individual circuit portion (i.e. to scan inputs of each circuit portion), in practice the number and complexity of I/O connections required to do so may be prohibitively high. However, circuit portions according to embodiments of the present invention can advantageously be arranged to form a scan chain, by inputting a scan output signal from a circuit portion to the scan input of a next circuit portion in the chain. This may allow scan test patterns to be loaded into a large number of circuit portions and the resulting states observed quickly and easily.

Thus, according to a second aspect of the present invention there is provided a scan chain comprising a first circuit portion according to the first aspect of the invention disclosed herein and a second circuit portion comprising a scan input and a scan output, wherein the scan input of the second circuit portion is arranged to receive the scan output signal of the first circuit portion. The second circuit portion may also be a circuit portion according to the first aspect of the invention described herein or it may be another scannable circuit portion known in the art per se.

A scan chain may be formed from as little as two circuit portions, but in a set of embodiments the scan chain comprises one or more further circuit portions whose scan input is arranged to receive the scan output signal of a previous circuit portion in the scan chain. The further circuit portion(s) may be according to the first aspect of the invention described herein. The scan chain may comprise circuit portions connected in series to produce a scan chain of any desired length. In some embodiments the scan chain comprises ten or more, 50 or more or 100 or more circuit portions connected in series.

It will be appreciated that connecting the scan inputs and outputs of circuit portions in this way means that the scan chain can be operated as a shift register when the circuit portions are operated in the scan mode. A scan input of the first circuit portion comprises a scan chain input and a scan output signal of the final circuit portion comprises a scan chain output signal. A desired scan test state for each circuit portion can be loaded in with appropriate control of the scan chain input, because states applied to this scan input cascade through to the subsequent circuit portions in the chain. Furthermore, resulting states of the circuit portions after a period of operation (e.g. in the operational mode or the capture mode) can be read out with appropriate sampling of the scan chain output signal.

Preferably, the circuit portions of the scan chain share a common scan clock signal. The circuit portions of the scan chain may share common control signals such as a test mode signal and/or a scan enable signal. In other words the circuit portions of the scan chain may all operated in the operational mode or all operate in the scan mode.

Arranging circuit portions into a scan chain can facilitate testing of a large number of circuit portions using only a single scan chain input and a single scan chain output. This may facilitate testing of devices featuring a large number of circuit portions. In some embodiments the scan chain includes most or all scannable circuit portions of a device.

According to a third aspect of the present invention there is provided a device comprising the circuit portion as disclosed herein. The device may comprise a plurality of circuit portions as disclosed herein. The circuit portions may be arranged to form a scan chain as disclosed above. In other words, the device may comprise a scan chain according to the second aspect of the present invention.

As explained above, the mode of the circuit portion (or circuit portions of a scan chain) may be controlled by one or more control signals. Scan data must also be provided for testing the circuit portion(s). Control signal(s) and/or scan data may be provided by internal testing circuitry of the device. However, in some embodiments separate testing apparatus generates the control signal(s) and/or scan data.

Thus, the invention extends to a system comprising a device as disclosed herein and testing apparatus arranged to provide scan data to one or more circuit portions of the device (e.g. to a scan chain input) and/or to receive scan data from one or more circuit portions of the device (e.g. from a scan chain output) and/or to control a mode of one or more circuit portions of the device. The testing apparatus may comprise automatic test pattern generation (ATPG) apparatus (i.e. apparatus arranged to provide ATPG test patterns as the scan data, e.g. generated by ATPG software running on the testing apparatus or generated on a separate device and transferred to the testing apparatus).

Features of any aspect or embodiment described herein may, wherever appropriate, be applied to any other aspect or embodiment described herein. Where reference is made to different embodiments, it should be understood that these are not necessarily distinct but may overlap.

### BRIEF DESCRIPTION OF THE DRAWINGS

One or more non-limiting examples will now be described, by way of example only, and with reference to the accompanying figures in which:

FIG. 1 is a schematic diagram of a circuit portion according to an embodiment of the present invention;

FIG. 2 is a schematic diagram of a system according to an embodiment of the present invention;

FIG. 3 is a schematic diagram of the scan chain of the system of FIG. 2; and

FIG. 4 is a schematic diagram of a circuit portion according to another embodiment of the present invention.

FIG. 5 is a schematic diagram of a circuit portion according to another embodiment of the present invention.

### DETAILED DESCRIPTION

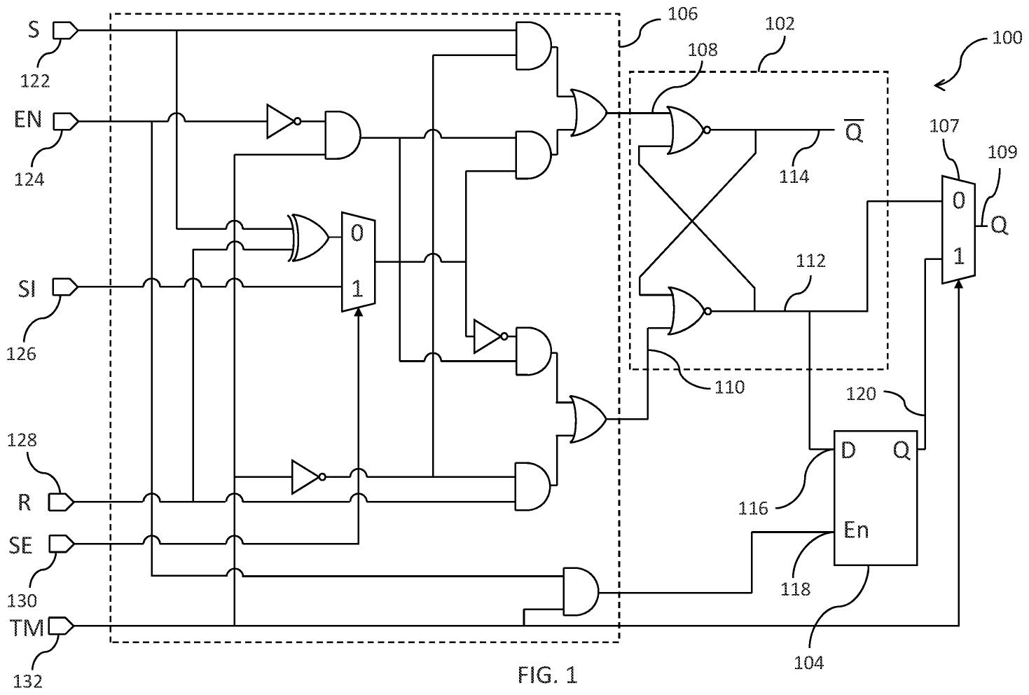

FIG. 1 shows a circuit portion 100 comprising a logic portion 102, a first scan latch 104, configuration circuitry 106 and an output multiplexer 107. In this embodiment the logic portion 102 is an SR latch and the first scan latch 104 is a slave D-latch.

The SR latch 102 has a set input 108, a reset input 110, an output 112 and a negative output 114. The inputs 108, 110 and outputs 112, 114 are connected via two NOR gates to produce standard SR latch behaviour.

The slave D-latch 104 comprises a data input 116, an enable input 118 and a scan output 120. The data input 116 is connected to the output 112 of the SR latch 102.

The output multiplexer 107 selects either the output 112 of the SR latch 102 or the scan output 120 of the slave D-latch 104 to output to a circuit portion output 109.

The configuration circuitry 106 comprises several inputs: an operational set input 122, a scan clock input 124, a scan input 126, an operational reset input 128, a scan enable input 130 and a test mode input 132. The configuration circuitry 106 comprises logic arranged to cause the circuit portion 100 to operate in an operational mode, a scan mode or a capture mode according to the states of the scan enable input 130 and the test mode input 132.

To operate the circuit portion 100 in the operational mode, the scan enable input 130 and the test mode input 132 are driven low. The configuration circuitry 106 then operates to simply connect the operational set and reset inputs 122, 128 to the set and reset inputs 108, 110 of the SR latch 102. Because the test mode input 132 is driven low, the output multiplexer 107 outputs the output 112 from the SR latch 102. The circuit portion 100 thus acts as an asynchronous SR latch.

The circuit portion 100 is also operable in a scan mode to facilitate testing. To operate the circuit portion 100 in the scan mode, test mode input 132 is driven high. The scan enable input 130 is driven high to enable shifting of scan test data into the circuit portion 100. This causes the configuration circuitry 106 to connect the scan input 126 to the reset input 108 and an inverted version of the scan input 126 to the set input 110, both gated by an inverted version of a scan clock signal applied to the scan clock input 124. The configuration circuitry 106 thus configures the SR latch 102 to operate as the memory element of a second scan latch (in this case a master D-latch) having the scan input 126 as a data input and the output 112 of the SR latch 102 as a data output, clocked by an inverted version of the scan clock signal.

The scan clock input 124 is connected to the enable input 118 of the slave latch 104 (i.e. the slave latch 104 is clocked by the non-inverted scan clock signal).

Thus, in the scan mode, on a falling edge of the scan clock signal the current state of the scan input 126 is stored at the output of the SR latch 102. In the scan mode a user can set the state of the SR latch 102 as desired through appropriate control of the scan input 126.

On the subsequent rising edge, this state is stored by the slave latch 104 and output from the circuit portion via the scan output 120 and the output multiplexer 107. In other words, in the scan mode 104 the circuit portion 100 outputs a delayed version of a signal applied to the scan input 126 and stored in the SR latch 102.

Once scan test data has been loaded into the circuit portion 200, the scan enable input 130 is driven low to re-connect the operational set and reset inputs 122, 128 to the set and reset inputs 108, 110 of the SR latch 102 and put the circuit portion 200 into the capture mode. The next pulse of the scan clock signal then causes a “capture cycle” where the result of the test data is captured in the slave D-latch 104. The scan enable input 130 is then driven high again to put the circuit portion 200 back into the scan mode to shift out the result.

By being operable in the operational, scan and capture modes, the circuit portion 100 effectively acts as a scan flip-flop. The circuit portion 100 may be used as part of combinatorial logic in a device such as a buck converter.

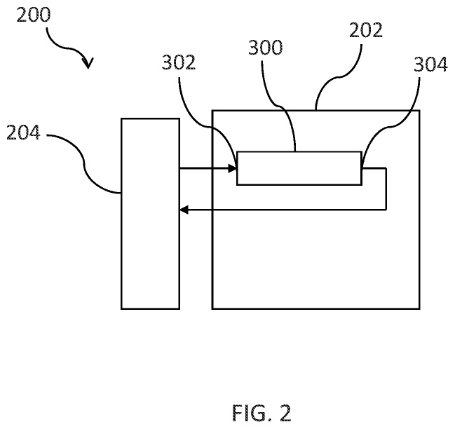

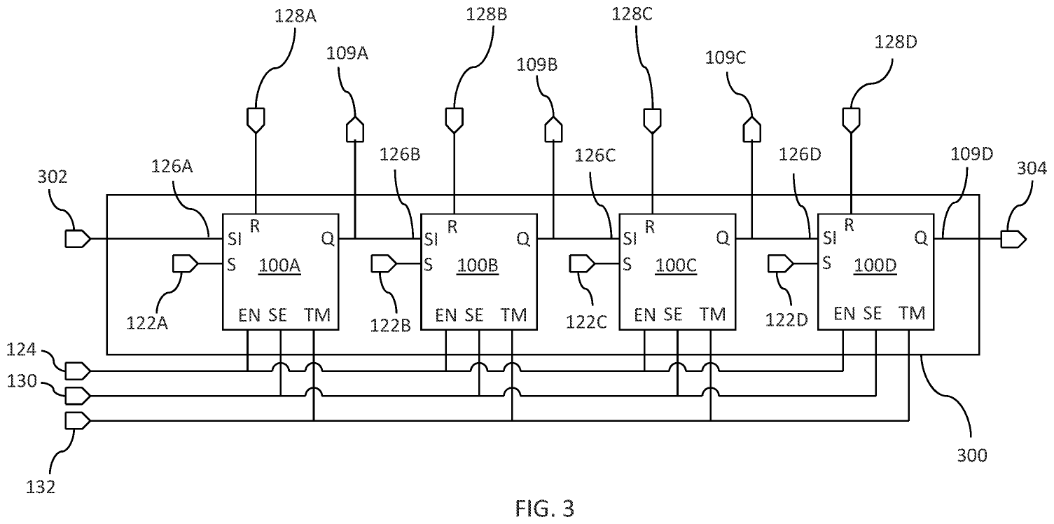

FIG. 2 shows a system 200 comprising a device 202 and testing apparatus 204. The device 202 comprises a plurality of circuit portions as described above that operate asynchronously in an operational mode to provide a desired device functionality (e.g. buck conversion). The circuit portions are also operable in the scan and capture modes for testing of the device 202 under the control of the testing apparatus 204. To facilitate this testing, the circuit portions are arranged in a scan chain 300, which will now be described in more detail with reference to FIG. 3.

FIG. 3 shows a scan chain 300 comprising a plurality of circuit portions 100A, 100B, 100C and 100D as described above (four are illustrated in FIG. 3 but in reality the scan chain 300 may comprise many more). Each of the circuit portions 100A-D comprises operational set and reset inputs 122A-D, 128BA-D and circuit portion outputs 109A-D. The circuit portions 100A-D share common scan clock, scan enable and test mode inputs 124, 130, 132.

The set and reset inputs 122A-D, 128A-D of the circuit portions 100A-D may not be directly connected or indeed at all closely related when operating in the operational mode to provide the desired functionality of the device 200. However, the scan inputs and outputs of the circuit portions 100A-D are connected in series to form the scan chain 300. The output 109A of the first circuit portion 100A is connected to the scan input 126B of the second circuit portion 100B, the output 109B of the second circuit portion 100B is connected to the scan input 126C of the third circuit portion 100C, and so on. The scan input 126A of the first circuit portion 100A provides a scan chain input 302 of the scan chain 300 and the output 109D of the final (fourth) circuit portion 100D is provides a scan chain output 304.

The circuit portions 100A-D of the scan chain 300 are put into the scan mode by the testing apparatus 204 asserting logic high signals at the scan enable and test mode inputs 130, 132. When operated in the scan mode, the circuit portions 100A-D form a shift register that can be used with appropriate control of the scan chain input 302 to load in scan test states for each of the circuit portions 100A-D, and/or to read out states of each of the circuit portions 100A-D from the scan chain output 304 after a capture cycle.

In one example of a testing process, the testing apparatus 204 puts the circuit portions 100A-D into the scan mode and inputs a scan test pattern into the scan chain 300. The testing apparatus 204 then puts the circuit portions 100A-D into the capture mode and performs a capture cycle by lowering the scan enable input 130. The states of each of the circuit portions 100A-D set by the scan test pattern propagates through the asynchronous logic and the result is captured in the slave D-latches of the circuit portions 100A-D. Finally, the testing apparatus 204 re-asserts the scan enable input 130 and reads out the capture results from the scan chain output 304.

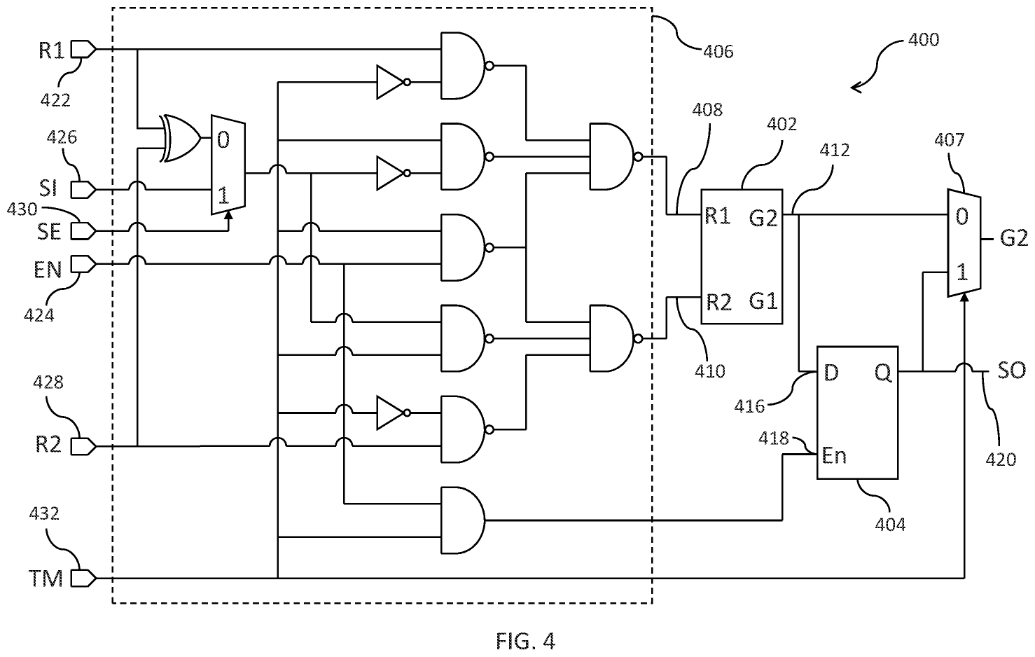

FIG. 4 shows another circuit portion 400 comprising a logic portion 402, a first scan latch 404, configuration circuitry 406 and an output multiplexer 407. In this embodiment the logic portion 402 is a MUTEX latch, but the circuit portion 400 is otherwise arranged similarly to the circuit portion 100 described above. The first scan latch 104 is a slave D-latch.

The MUTEX latch 402 has a first request input 408, a second request input 410 and a grant output 412 (the MUTEX latch 402 also has another grant output G1 but this is not used for anything in this embodiment). The MUTEX latch 402 is configured to assert a signal on the grant output 412 only if the second request input 410 receives an asserted signal before the first request input 410.

The slave D-latch 404 comprises a data input 416, an enable input 418 and a scan output 420. The data input 416 is connected to the grant output 412 of the MUTEX latch 402. The output multiplexer 407 comprises a circuit portion output 409 that is connected to either the output 412 of the MUTEX latch 402 or the scan output 420 of the slave D-latch 404.

The configuration circuitry 406 comprises several inputs: an operational first request input 422, a scan clock input 424, a scan input 426, an operational second request input 428, a scan enable input 430 and a test mode input 432. The configuration circuitry 406 comprises logic arranged to cause the circuit portion 400 to operate in an operational mode, a scan mode or a capture mode according to the states of the scan enable input 430 and the test mode input 432.

The circuit portion 400 is operable in the operational mode by driving the scan enable input 430 and the test mode input 432 low. The circuit portion 400 is operable in the scan mode by driving the scan enable input 430 and the test mode input 432 high. The circuit portion 400 is operable in the capture mode by driving the scan enable input 430 low and the test mode input 432 high. The circuit portion 400 can be thus operated and tested in a corresponding manner to the circuit portion 100 described above.

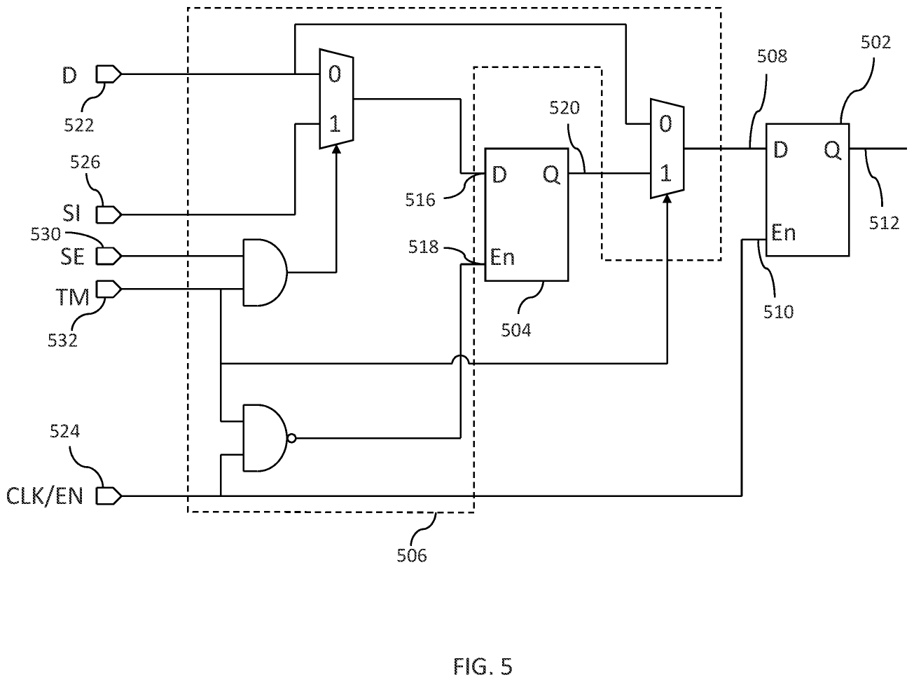

FIG. 5 shows another circuit portion 500 comprising a logic portion 502, a first scan latch 504 and configuration circuitry 506. In this embodiment the logic portion 502 is a D-latch and the first scan latch 504 is a master D-latch.

The D-latch 502 has a data input 508, an enable input 510 and a data output 512. The D-latch 402 is configured to latch the state of the data input 508 at the data output 512 when a logic high signal is asserted on the enable input 510.

The master D-latch 504 comprises a data input 516, an enable input 518 and a data output 520.

The configuration circuitry 506 comprises several inputs: an operational data input 522, a scan clock/enable input 524, a scan input 526, a scan enable input 530 and a test mode input 532. The configuration circuitry 506 comprises logic arranged to cause the circuit portion 500 to operate in an operational mode, a scan mode or a capture mode according to the states of the scan enable input 530 and the test mode input 532.

The circuit portion 500 is operable in the operational mode by driving the scan enable input 530 and the test mode input 532 low. In the operational mode, the operational data input 522 receives asynchronous data which is passed directly to the data input 508 of the D-latch 502. The scan clock/enable input 524 receives an asynchronous enable signal which is passed directly to the enable input 510 of the D-latch 502. The D-latch 502 operates asynchronously based on said inputs to produce an operational output signal on the data output 512.

The circuit portion 500 is operable in the scan mode by driving the scan enable input 530 and the test mode input 532 high. In the scan mode, the data output 520 of the master D-latch 504 is connected to the data input 508 of the D-latch 502, and the scan input 526 is connected to the data input 516 of the master D-latch 504. The D-latch 502 is clocked by a clock signal received at the scan clock/enable input 524 and the master D-latch 504 is clocked by an inverted version of this clock signal. The D-latch 502 operates as a slave latch of a synchronous flip-flop formed by the D-latch 502 and the master D-latch 504, clocked by the clock signal. Scan test data may be shifted into the flip-flop through appropriate control of the scan input 526.

The circuit portion 500 is operable in the capture mode by driving the scan enable input 530 low and the test mode input 532 high. In the capture mode, the operational data input 522 is reconnected to the data input 516 of the master D-latch 504. The next pulse of the scan clock signal then causes a “capture cycle” where the result of the test data is captured in the slave D-latch 502. The scan enable input 530 is then driven high again to put the circuit portion 500 back into the scan mode to shift out the result.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A circuit portion comprising:
an operational input and a scan input;
a logic portion comprising at least one input and at least one output; and
a first scan latch comprising at least one input and at least one output; wherein the circuit portion is arranged to operate in:
an operational mode in which the operational input is connected to an input of the logic portion and the logic portion operates as an asynchronous latch to generate an operational output signal at an output of the logic portion; and
a scan mode in which the logic portion operates as part of a second scan latch, and the first scan latch and the second scan latch form a synchronous flip-flop comprising an input connected to the scan input and arranged to generate a scan output signal.

2. The circuit portion of claim 1, wherein the logic portion is arranged to operate as a memory element of the second scan latch in the scan mode.

3. The circuit portion of claim 1, wherein the first scan latch is a D-latch.

4. The circuit portion of claim 1, wherein the second scan latch is a D-latch.

5. The circuit portion of claim 1, wherein:
the synchronous flip-flop is a master-slave type flip-flop formed from master and slave latches;
the first scan latch is the master latch and the second scan latch is the slave latch;
the input of the first scan latch is connected to the scan input; and
in the scan mode, the input of the logic portion is connected to the output of the first scan latch and the scan output signal is generated at the output of the logic portion.

6. The circuit portion of claim 1, wherein:
the synchronous flip-flop is a master-slave type flip-flop formed from master and slave latches;
the second scan latch is the master latch and the first scan latch is the slave latch;
the input of the first scan latch is connected to the output of the logic portion; and
in the scan mode, the scan input is connected to the input of the logic portion and the scan output signal is generated at the output of the first scan latch.

7. The circuit portion of claim 1, comprising a scan clock input arranged to receive a scan clock signal that clocks the synchronous flip-flop.

8. The circuit portion of claim 7, arranged to gate an input of the logic portion with an enable signal derived from the scan clock signal when in the scan mode.

9. The circuit portion of claim 1, arranged to operate in a capture mode in which the operational input is connected to the input of the logic portion and the logic portion operates as part of the second scan latch of the synchronous flip-flop.

10. The circuit portion of claim 1, comprising a scan enable input arranged to receive a scan enable signal that controls whether the operational input is connected to the input of the logic portion.

11. The circuit portion of claim 1, comprising a test mode input arranged to receive a test mode signal that controls enabling of the first scan latch.

12. The circuit portion of claim 1, wherein the logic portion comprises a mutual-exclusion (MUTEX) element.

13. The circuit portion of claim 1, wherein the logic portion comprises a set-reset latch.

14. The circuit portion of claim 1, comprising an operational output for outputting the operational output signal and a separate scan output for outputting the scan output signal.

15. The circuit portion of claim 1, comprising a single output for outputting the operational output signal and the scan output signal.

16. A scan chain comprising a first circuit portion and a second circuit portion according to claim 1, wherein the scan input of the second circuit portion is arranged to receive the scan output signal of the first circuit portion.

17. The scan chain of claim 16, comprising ten or more circuit portions connected in series.

18. A system comprising a device and testing apparatus, the device comprising the scan chain of claim 15, wherein the testing apparatus is arranged to provide scan data to one or more circuit portions of the device.

19. The system of claim 18, wherein the testing apparatus is arranged to receive scan data from one or more circuit portions of the device.

20. The system of claim 18, wherein the testing apparatus is arranged to provide automatic test pattern generation patterns as the scan data.
